(19) United States
(12) Patent Application Publication
(10) Pub. No.: US 2026/0357423 A1
(43) Pub. Date: Nov. 12, 2026

(54) METHOD OF MANUFACTURING HIGHLY CONDUCTIVE THIN FILM

(71) Applicant: GLOBAL FRONTIER CENTER FOR MULTISCALE ENERGY SYSTEMS, Seoul (KR)

(72) Inventors: Mansoo CHOI, Seoul (KR); Jooyeon SHIN, Seoul (KR)

(21) Appl. No.: 19/716,332

(22) Filed: Jun. 23, 2026

Related U.S. Application Data
(63) Continuation-in-part of application No. PCT/KR2025/003553, filed on Mar. 19, 2025.

(30) Foreign Application Priority Data
Apr. 4, 2024 (KR) 10-2024-0045682

(51) Int. Cl. C23C 16/448; C23C 16/507; C23C 16/52

(52) U.S. Cl. CPC C23C 16/4486; C23C 16/507; C23C 16/52

(57) ABSTRACT

A method of depositing a conductive thin film is disclosed. The method comprises: generating charged molecular cluster aerosols of a conductive material in a discharge chamber under ambient temperature and atmospheric pressure conditions by forming an asymmetric electric field using a discharge electrode unit comprising a plurality of electrodes having different geometries, wherein discharge occurs at one electrode to vaporize and adiabatically expand the electrode material, producing charged molecular cluster particles having a size of less than 2 nm; and introducing the charged molecular cluster aerosols into a deposition chamber fluidly connected to the discharge chamber, and accelerating the aerosols toward a substrate by applying an electric field of opposite polarity via a third electrode, thereby depositing a highly conductive thin film without post-deposition annealing or vacuum processing.

### CROSS REFERENCE TO RELATED APPLICATIONS

This application is a continuation-in-part of PCT application PCT/KR2025/003553 filed Mar. 19, 2025 to CHOI et al., which claims the benefit of priority based on Korean Patent Application No. 10-2024-0045682 filed on Apr. 4, 2024, the entire disclosure of all two are incorporated as a part of this specification.

### FIELD OF THE INVENTION

The present disclosure relates to a method of manufacturing a highly conductive thin film, and more particularly, to a method of manufacturing a highly conductive thin film by preparing charged molecular cluster aerosols at the level of several Å that is charged at ambient temperature and atmospheric pressure, and accelerating it with an electric field under ambient temperature and atmospheric pressure conditions to attach it to a substrate.

### BACKGROUND OF THE INVENTION

As the demand for electronic components included in solar cells, batteries, displays, and memory increases day by day, the importance of conductive thin film formation technology is growing. In particular, with the miniaturization and integration of devices, the importance of deposition technologies capable of uniformly forming thin films with high conductivity, i.e., low resistivity, is increasing.

Existing thin film deposition technologies include chemical vapor deposition (CVD), atomic layer deposition (ALD), physical vapor deposition (PVD), thermal deposition, and the like. While all of these technologies may produce thin films with excellent conductivity using various materials, they are limited by impurity contamination and high costs associated with large-scale vacuum equipment. Specifically, for example, when depositing gold (Au) using vacuum thermal deposition, a resistivity approximately three times that of the bulk material may be obtained, but the deposition thickness is about 30 nm, and when depositing TiN thin films using the ALD method, the deposition thickness may be reduced to approximately 5 nm, but it was found to possess a resistivity more than 100 times that of the bulk material.

Further, there is a spark discharge method which is an atmospheric process technology attracting attention for its ability to resolve issues such as reduced purity due to impurity contamination and high costs associated with large-scale vacuum equipment. According to the spark discharge method, thin films may be deposited by preparing nano-aerosols ranging in size from a few to tens of nanometers at ambient temperature and atmospheric pressure. However, since the nano-aerosols prepared by the spark discharge method are only a few to tens of nanometers in size, the final thin films created using them require an additional annealing process to satisfy the required electrical properties due to their high contact resistance. In the case of gold aerosol nanoparticles produced by the spark discharge method, the resistivity value was found to be approximately 40 times higher than that of the bulk material.

### SUMMARY OF THE INVENTION

The present disclosure aims to provide a new method of depositing a highly conductive thin film without additional processes such as an annealing process by preparing charged molecular cluster aerosols of several Å in size at ambient temperature and atmospheric pressure and then accelerating the aerosols with an electric field to attach the same to a substrate. Technical Solutions

In order to achieve the above objects, the present disclosure provides a method of depositing a conductive thin film including:
generating charged molecular cluster aerosols of a conductive material by forming an asymmetric electric field under ambient temperature and atmospheric pressure conditions in a discharge chamber provided with a discharge electrode unit including a plurality of electrodes having different shapes, thereby causing a discharge to occur at one of the electrodes; and
introducing the molecular cluster aerosols into a deposition chamber fluidly connected to the discharge chamber and equipped with a substrate, and accelerating the molecular cluster aerosols with an electric field to attach the molecular cluster aerosols to the substrate.

In the method of the present disclosure, each charged molecular cluster aerosol may be an aggregate of molecules each having a size about 1 nm, and may be a charged nanoparticle having an overall size of 2 nm or less.

In the method of the present disclosure, the plurality of electrodes may include a first electrode connected to a power supply device and a second electrode which is a ground electrode, the first electrode and the second electrode may be spaced apart by a predetermined distance, and the deposition chamber may be provided with a third electrode in contact with the substrate.

In the method of the present disclosure, an electric field may be applied by applying, to the third electrode, a voltage of opposite polarity to a voltage applied to the first electrode.

In the present disclosure, a voltage of 1 to 10 kV may be applied to the first electrode, the second electrode may be grounded, a voltage of −1 to −10 kV may be applied to the third electrode, a discharge voltage may be 1 to 5,000 V

In the present disclosure, the first electrode may have a wire shape having a predetermined diameter, and the second electrode may have a plate shape having an opening part corresponding to the wire shape.

In the present disclosure, the distance between the first electrode and the second electrode may correspond to the diameter of the first electrode.

In the present disclosure, the charged molecular cluster aerosols may be unipolarly charged.

In the present disclosure, particle size distribution of the charged molecular cluster aerosols may be concentrated at 1 nm or less when measured using a measurement system comprising a differential mobility analyzer (DMA), a Faraday cup, and an electrometer.

In the present disclosure, the discharge electrode unit may comprise electrodes made of a conductive material selected from the group consisting of gold (Au), titanium (Ti), silver (Ag), palladium (Pd), copper (Cu), metal alloys thereof, and metal oxides including indium tin oxide (ITO).

In the present disclosure, a carrier gas comprising at least one of nitrogen, argon, helium, hydrogen, oxygen, and their mixtures may be injected into the discharge chamber at a flow rate of 0.1 to 100 l/min per electrode.

In the present disclosure, the deposited conductive thin Au film may have an RMS surface roughness of 0.7 nm or less as measured by atomic force microscopy (AFM).

In the present disclosure, the deposited conductive thin film may have a resistivity of less than 50 nΩ·m or less at a thickness of 10 nm.

In the present disclosure, the conductive thin film may have a thickness of 4 to 30 nm.

In the present disclosure, the diameter of the first electrode and the opening part diameter of the second electrode may be each independently 0.8 mm or more and 2 mm or less.

In the present disclosure, the distance between the first electrode and the second electrode may be 0.5 mm to 1.5 mm.

In the present disclosure, the discharge electrode unit may be provided in a plurality within the discharge chamber, and each discharge electrode unit independently injects a carrier gas.

In the present disclosure, the discharge in the discharge chamber may operate in a molecular cluster (MC) generation region that is sequentially identified in a current-voltage (I-V) characteristic curve as one of four distinct regions comprising a corona discharge region, the molecular cluster generation region, a transition region (Tr), and a spark discharge region, with increasing applied voltage.

In the present disclosure, the slope of the I-V characteristic curve may vary by less than 50% within the corona discharge region and increases by more than 50% at the beginning voltage of the molecular cluster generation region, thereby defining a boundary between the corona discharge region and the molecular cluster generation region.

### EFFECT OF THE INVENTION

According to the present disclosure, it is possible to manufacture a highly conductive thin film with thin thickness and low resistivity without additional processes by preparing charged molecular cluster aerosols of several Å in size from a low-temperature plasma made near the first electrode at ambient temperature and atmospheric pressure, and then accelerating it with an electric field to attach it to a substrate that is attached on the third electrode.

### BRIEF DESCRIPTION OF THE DRAWINGS

FIG. 1A is a schematic diagram of an atmospheric pressure plasma discharge chamber for preparing charged molecular cluster aerosols and a deposition chamber for manufacturing a highly conductive thin film by accelerating the generated charged molecular cluster aerosols with an electric field and then attaching it to a substrate according to an embodiment.

FIG. 1B is a schematic diagram showing an electric field scheme inside a deposition chamber of FIG. 1A.

FIG. 2A shows an atmospheric pressure plasma image (A) used in the present method and a graph (B) showing a discharge voltage between two electrodes over time measured with an oscilloscope.

FIG. 2B shows a conventional spark discharge image (C) and a graph (D) showing a spark discharge voltage between two electrodes over time measured with an oscilloscope.

FIG. 3 is a TEM image of Au molecular cluster aerosols prepared in Example 1.

FIGS. 4A to 4D are atomic force microscope (AFM) images comparing surface roughness of an Au thin film according to Example 1 and Au thin films according to Comparative Examples 1, 2 and 3, respectively.

FIG. 5 shows resistivity measurement results for the thin films shown in FIGS. 4A and 4C.

FIG. 6 is a TEM image of TiN molecular cluster aerosols according to Example 2.

FIG. 7 shows resistivity measurement results for a TiN molecular cluster (MC) thin film prepared from the TiN molecular cluster aerosols shown in FIG. 6.

FIG. 8 is a schematic diagram of a measurement system for measuring a particle size distribution of molecular cluster aerosols.

FIG. 9A is a graph showing a concentration (dN/dlogdp)-based particle size distribution of Au charged particles generated by spark discharge, and FIG. 9B is a graph showing a concentration-based particle size distribution of Au charged particles generated by the method according to the present disclosure.

FIG. 10A is a graph showing the I-V characteristics when using Au electrodes from power supply, illustrating four sequential regions with increasing applied voltage: a corona discharge region, a molecular cluster (MC) generation region, a transition region, and a spark discharge region.

FIG. 10B is a graph showing the I-V characteristics when using a tungsten (W) electrode, which is known to generate only ions without producing molecular clusters from power supply, under corona discharge conditions.

FIG. 10C is an enlarged Au I-V graph showing the difference in current-voltage slope between the corona discharge region and the molecular cluster generation region in FIG. 10A.

FIG. 10D is an enlarged W I-V graph showing a constant current-voltage slope in the corona discharge region of FIG. 10B, without a slope transition.

FIG. 10E is a graph comparing the I-V curve slopes of Au with that of a W electrode, indicating that the Au electrodes exhibits a clear slope transition corresponding to the transition from a corona region to an MC generation region, whereas the W electrode exhibits no clear slope transition.

### DETAILED DESCRIPTION OF THE INVENTION

Hereinafter, the present disclosure will be described with reference to specific embodiments and drawings.

The present disclosure relates to a method of manufacturing a highly conductive thin film having a thin thickness without additional annealing processes by preparing charged molecular cluster aerosols of a size of several Å from a low-temperature plasma made near to the first electrode at ambient temperature and atmospheric pressure, and then accelerating those with an electric field to attach it to a substrate that is attached on the third electrode.

The method according to the present disclosure includes generating charged molecular cluster aerosols of a conductive material by forming an asymmetric electric field under ambient temperature and atmospheric pressure conditions in a discharge chamber provided with a discharge electrode unit including a plurality of electrodes having different shapes, thereby causing a discharge to occur at one of the electrodes, and introducing the molecular cluster aerosols into a deposition chamber fluidly connected to the discharge chamber and equipped with a substrate, and accelerating the molecular cluster aerosols with an electric field to attach the molecular cluster aerosols to the substrate.

In the method according to the present disclosure, a “charged molecular cluster aerosol” refers to a nanoparticle formed by the aggregation of several charged molecules having a size of less than 2 nm. Here, the term “size” refers to the diameter of the nanoparticle, and in the case of an irregular shape, it refers to the maximum diameter. Unlike nanoaerosols of several nm (at least larger than 2 nm) generated by conventional spark discharge, charged molecular cluster aerosols are nanoparticles of a size of less than 2 nm, or about 1 nm or less, formed by the aggregation of several molecules, and are charged.

In the present disclosure, ambient temperature refers to a temperature that is not heated or cooled, and may generally refer to 15 to 30 °C or 20 to 25 °C. In addition, atmospheric pressure refers to an atmospheric pressure state (100 to 110 kPa) that is not a pressurized or depressurized state.

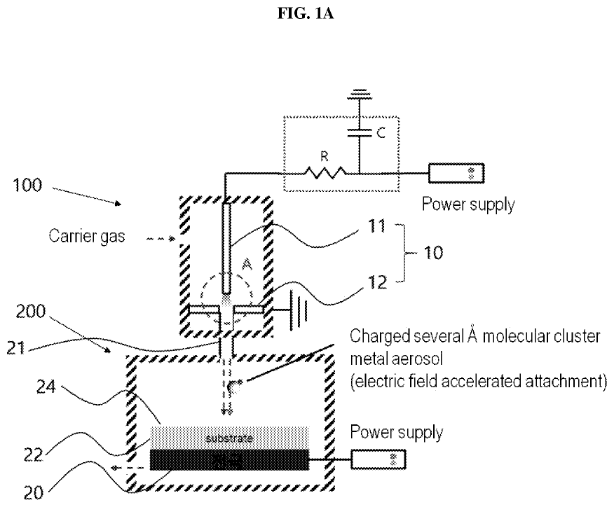

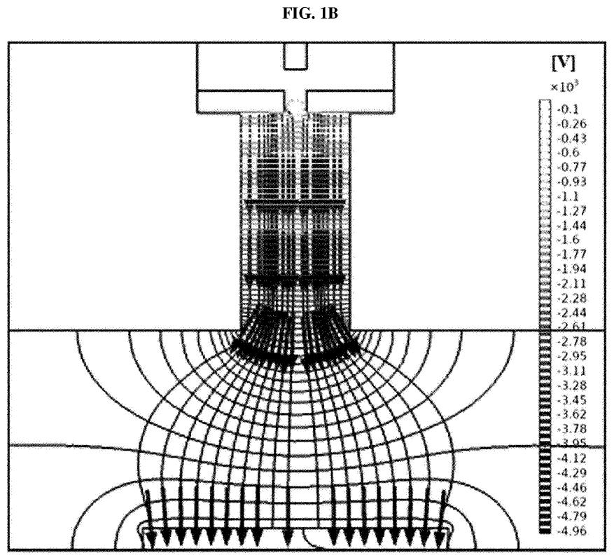

FIG. 1 schematically illustrates the device configuration and electric field scheme of an embodiment of the present disclosure, wherein the device includes power supplies, a RC circuit, a discharge chamber 100 for preparing charged molecular cluster aerosols (A) and a deposition chamber 200 for manufacturing a thin film by introducing the generated molecular cluster aerosols (A) and attaching them with an electric field acceleration.

The discharge chamber 100 is provided with a discharge electrode unit 10, and the discharge electrode unit 10 includes a first electrode 11 connected to a power supply device and a second electrode 12 which is a ground electrode. The first electrode 11 may be connected to an RC circuit or may be connected directly to the power supply device without an RC circuit. The first electrode 11 and the second electrode 12 have different shapes, and since voltage is applied only to the first electrode 11 and the second electrode 12 is grounded, as a result, the electric field near the first electrode 11 and the electric field near the second electrode 12 may be asymmetrically created, and discharge may occur only at the electrode where a high electric field is generated. In addition, the first electrode 11 and the second electrode 12 are spaced apart by a predetermined distance. The first electrode 11 and the second electrode 12 do not need to be made of the same material.

According to an embodiment, the first electrode 11 may be in the shape of a wire having a predetermined diameter, and the second electrode 12 may be in the shape of a plate having an opening part corresponding to the diameter. Since the diameter of the first electrode 11 is smaller than the size of the second electrode 12, when a potential difference is applied between the two electrodes, an asymmetric electric field may be formed in which an electric field of greater strength is formed around the first electrode 11 than near the second electrode 12. Atmospheric pressure plasma may be generated only near the first electrode 11, where a larger electric field is generated near the first electrode 11, thereby evaporating the material of the first electrode 11 and generating molecular cluster aerosols of several Å in size near the first electrode 11. Conversely, the size of the second electrode 12 may be made smaller than that of the first electrode 11 to generate atmospheric pressure plasma only near the second electrode 12 and evaporate the material of the second electrode 12, thereby generating molecular cluster aerosols.

The diameter of the first electrode 11 and the opening part diameter of the second electrode 12 may be the same or different from each other, and each may independently be 0.1 mm or more, 0.2 mm or more, 0.3 mm or more, 0.4 mm or more, 0.5 mm or more, 0.6 mm or more, 0.7 mm or more, 0.8 mm or more, 0.9 mm or more, or 1 mm or more, and 5 mm or less, 4 mm or less, 3 mm or less, 2 mm or less, or 1.5 mm or less. According to a preferred embodiment, it may be 0.8 mm or more and 2 mm or less. The diameter of the first electrode 11 and the opening part diameter of the second electrode 12 are not limited to the above and only need to be capable of causing a discharge.

The distance between the first electrode 11 and the second electrode 12 may be 0.1 mm or more, 0.2 mm or more, 0.3 mm or more, 0.4 mm or more, 0.5 mm or more, 5 mm or less, 4 mm or less, 3 mm or less, 2 mm or less, or 1.5 mm or less, based on the distance between the center of the end part of the first electrode 11 adjacent to the second electrode 12 and the center of the opening part of the second electrode, and preferably 0.5 to 1 mm, but is not necessarily limited thereto.

When the first electrode 11 is in the shape of a wire and the second electrode 12 is in the shape of a plate, the area of the second electrode 12 may be in the range of 9 mm² to 400 mm², but is not necessarily limited thereto. The plate shape is also not limited to square, rectangular, circular, etc.

When the second electrode 12 is larger than the first electrode 11 and grounded, it has an asymmetric structure in which a strong electric field is generated only near the first electrode 11 when voltage is applied to the first electrode 11 from the power supply device.

The discharge chamber 100 generates molecular cluster aerosols (A) by applying a predetermined voltage to the first electrode 11 under ambient temperature and atmospheric pressure conditions.

The voltage applied to the first electrode 11 may be a positive voltage or a negative voltage. The magnitude of the voltage is 1 to 10 kV in absolute value, specifically, 1.1 kV or more, 1.2 kV or more, 1.3 kV or more, 1.4 kV or more, or 1.5 kV or more, and 6 kV or less, 5.5 kV or less, 5 kV or less, 4.5 kV or less, or 4 kV or less, for example, 3 to 4 kV.

The magnitude of the voltage applied to the first electrode 11 may be determined within a range such that no spark is formed between the first electrode 11 and the second electrode 12, and this may be influenced by the distance between the first electrode 11 and the second electrode 12. In other words, as the distance between the first electrode 11 and the second electrode 12 increases, the magnitude of the voltage at which a spark occurs increases, so the magnitude of the voltage applied to the first electrode 11 may also increase.

The materials of the first electrode 11 and the second electrode 12 in the discharge chamber 100 may be the same or different from each other and are composed of conductive materials including metals and metal alloys such as gold (Au), titanium (Ti), silver (Ag), palladium (Pd), copper (Cu), and metal oxides such as indium tin oxide (ITO).

The discharge electrode unit 10 including the first electrode 11 and the second electrode 12 may be one, and if necessary, two or more may be provided.

The discharge voltage occurring in the discharge chamber 100 may form a low-temperature plasma by the acceleration and collision of electrons or positive ions near the first electrode 11 due to the potential difference between the first electrode 11 and the second electrode 12.

The carrier gas injected into the discharge chamber may be an inert gas including nitrogen, argon, and helium, as well as hydrogen and oxygen, and may be injected at a rate of 0.1 to 100 l/min per electrode, for example, 1 to 10 l/min. The ‘carrier gas amount per electrode’ refers to the value obtained by dividing the total amount of carrier gas injected into the discharge electrode unit 10 by the number of electrodes. If there are multiple discharge electrode units 10, each discharge electrode unit may independently inject carrier gas.

The carrier gas enables the charged molecular cluster aerosols (A) generated in the discharge chamber 100 to move smoothly into the deposition chamber 200.

The deposition chamber 200 includes an inlet 21 into which the charged molecular cluster aerosols generated in the discharge chamber 100 is introduced, a substrate 22, and a third electrode 20 connected to a power supply device capable of applying voltage to the substrate 22.

The substrate 22 may be a conductive substrate such as a metal, semiconductor, or metal oxide, or a non-conductive substrate such as a polymer or glass, and may be used in various ways depending on the application of the final product. For example, a silicon substrate with a silicon dioxide thin film deposited thereon may be used.

A voltage of opposite charge to the voltage applied to the first electrode 11 is applied to the third electrode 20 located below the substrate 22, for example, when a positive voltage is applied to the first electrode 11, a negative voltage is applied to the third electrode 20, and the applied voltage may be −1 to −10 kV. For example, when a positive voltage of 3 to 4 kV is applied to the first electrode 11, the voltage applied to the third electrode 20 may be −4.0 to −6.0 kV. By doing this, the charged molecular clusters are accelerated by the electric field formed between the third electrode 20 and the second electrode 12 and attach to the substrate 22.

The substrate 22 may be made of a conductive material including metals and metal alloys such as gold (Au), titanium (Ti), silver (Ag), palladium (Pd), and copper (Cu), and metal oxides such as indium tin oxide (ITO), and does not need to be the same material as the first electrode 11 and the second electrode 12 in the discharge chamber.

The thin film 24 formed by depositing molecular cluster aerosols (A) on the substrate 22 has a very low surface roughness because the molecular cluster aerosols are attached by gathering molecular-sized nanoparticles formed by the vaporization and adiabatic expansion of the first electrode 11. For example, the RMS surface roughness (unit nm) measured from an atomic force microscope (AFM) image may be 0.7 nm or less, and preferably 0.5 nm or less, 0.45 nm or less, or 0.4 nm or less.

The thickness of the thin film may be formed from several nanometers to several hundred nanometers, for example, 4 to 300 nm. A gold thin film manufactured by the method according to the present disclosure may have a resistivity less than 50 nΩ·m or less even at a thin thickness of, for example, 10 nm. This level of resistivity is similar to the resistivity achievable in a 30 nm thick, thin film obtained by vacuum thermal evaporation. Below, an example of manufacturing a thin film using a device such as that shown in FIG. 1 is described in detail. The following examples are merely illustrative to aid in understanding the present disclosure and do not limit the scope of the disclosure.

### Example 1

### Manufacturing of Au Thin Film According to the Present Disclosure

An Au wire electrode (first electrode, 11) with a diameter of about 1 mm was prepared in a discharge chamber 100 at ambient temperature and atmospheric pressure. As the second electrode 12, an Au plate electrode (thickness 1 mm, area 25 mm²) with a hole (opening part) with a diameter of about 1 mm in the center was prepared. High-purity nitrogen (purity 99.99%) was used as the carrier gas and injected at a rate of 10 l/min per electrode. The first electrode 11 and the second electrode 12 are about 1 mm apart.

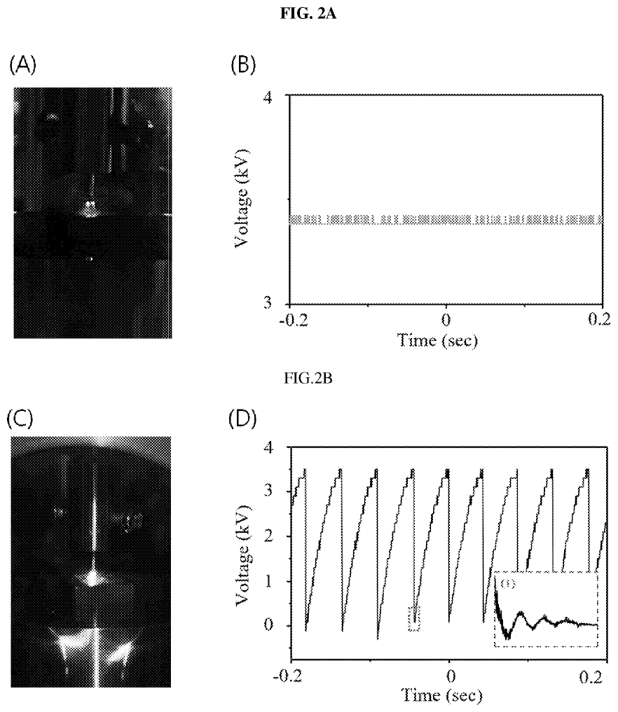

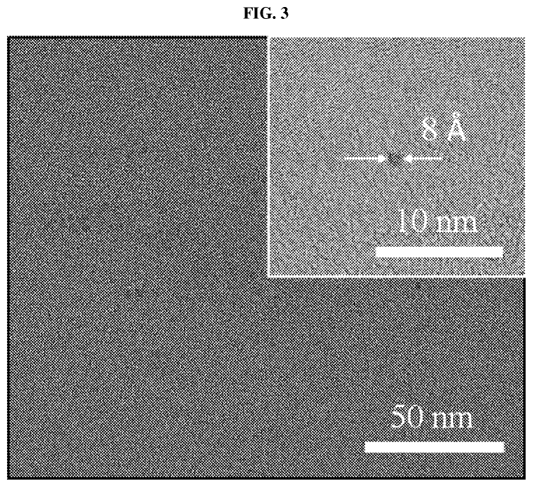

A positive voltage of about 3.5 kV was applied to the Au wire electrode (first electrode, 11) through a power supply device, and the second electrode 12 was grounded. RC circuit was designed as R=20 MΩ, C=2 nF, and ground. Under these conditions, it was confirmed that no spark discharge occurred and a low-temperature plasma was formed only near the Au wire electrode 11 (see FIG. 2A). The voltage between the first electrode and ground measured by an oscilloscope (Agilent DSO-X 3014 A) equipped with a high voltage probe (Tektronix P6015A) was constant (e.g., 2400 volts).

As may be seen from (A) and (B) of FIG. 2A, the discharge occurred only near the first electrode 11, causing the Au of the first electrode 11 to vaporize and undergo adiabatic expansion, thereby preparing positively charged Au molecular cluster aerosols with a size of several Å. FIG. 3 is a TEM image of the generated Au molecular cluster aerosol.

Copper (Cu) was used as the substrate electrode 20 in the deposition chamber 200, and a silicon substrate with a silicon dioxide (SiO₂) thin film deposited to a thickness of 100 nm was used as the substrate 22. A negative voltage of 5 kV was applied to the third electrode 20 to generate an electric field between the second electrode 12 and the third electrode 20, and the positively charged molecular cluster aerosols generated in the discharge chamber 100 were accelerated and attached in the electric field to deposit about 10 nm thick Au thin film on a silica coated silicon substrate.

### Comparative Example 1

### Manufacturing of Au Thin Film by Spark Discharge

A 25 nm thick Au thin film was deposited in the same manner as in Example 1, except that the voltage applied to the first electrode was 6.5 kV, and a spark discharge was generated by the acceleration and collision of electrons and positive ions at the two electrodes to form charged nano aerosols. As can be seen in (C) of FIG. 2B, it may be observed that discharge is occurring near both the first electrode and the second electrode, and as seen in (D) of FIG. 2B, the discharge voltage oscillates in a sawtooth pattern from the measurement of the oscilloscope.

From FIG. 2A and FIG. 2B, it can be seen that the discharge phenomenon of Comparative Example 1 is completely different from the discharge phenomenon observed in the present disclosure.

### Comparative Example 2

### Manufacturing of Au Thin Film by Vacuum Thermal Evaporation

On the same substrate as in Example 1, an Au thin film with a thickness of 30 nm was deposited by vacuum thermal evaporation under conditions of a temperature of 800 to 900 °C and a pressure of 10⁻⁸ Torr or less (0.0000013332 Pa or less).

### Comparative Example 3

### Manufacturing of Au Thin Film by Vacuum Sputter

On the same substrate as in Example 1, an Au thin film with a thickness of 10 nm was deposited by vacuum sputter under conventional sputtering conditions, including a chamber pressure of 10⁻⁸ Torr or less (0.0000013332 Pa or less).

### Au Thin Film Characteristic Analysis: Surface Roughness, Resistivity, and Resistivity Relative to Bulk

The surface roughness of the Au thin films manufactured in Example 1 and Comparative Examples 1 and 2 was measured using an atomic force microscope (AFM).

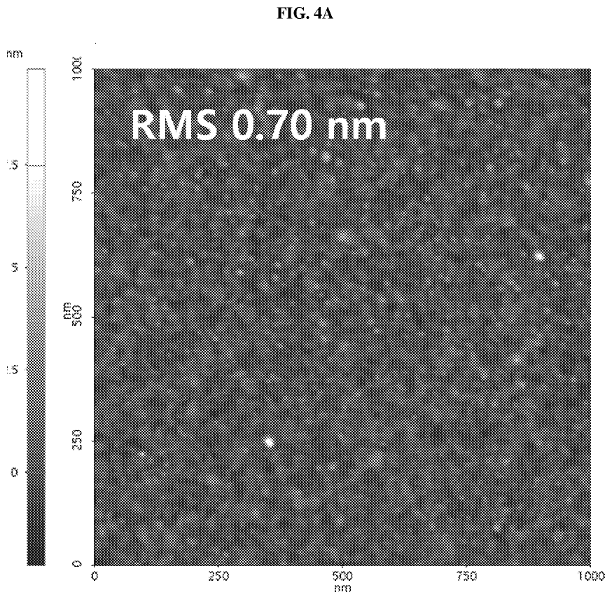

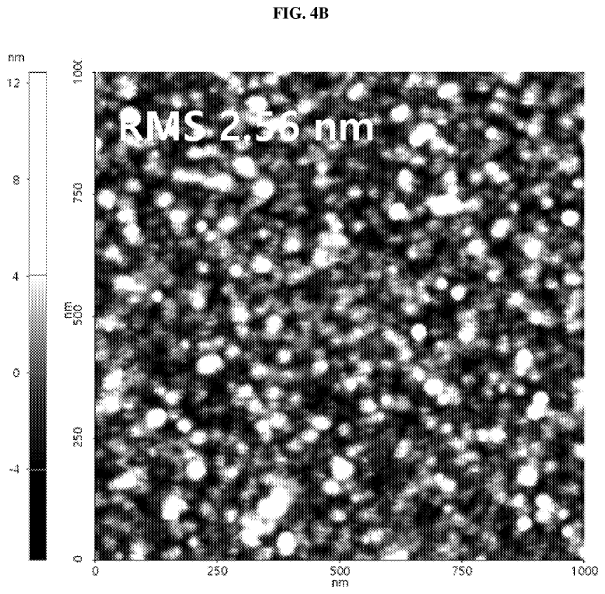

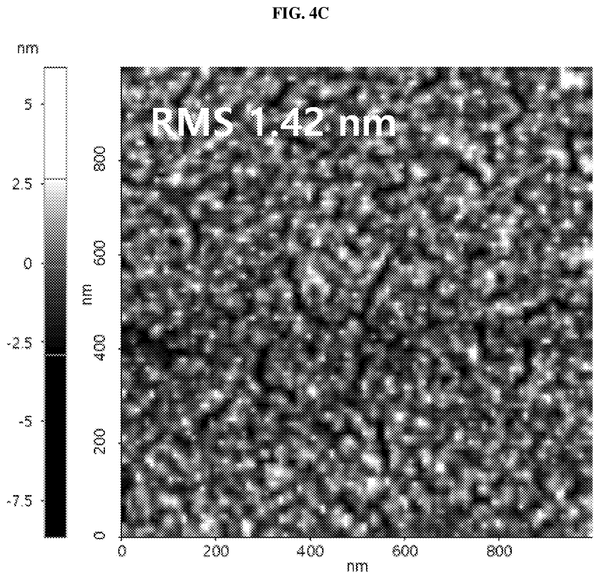

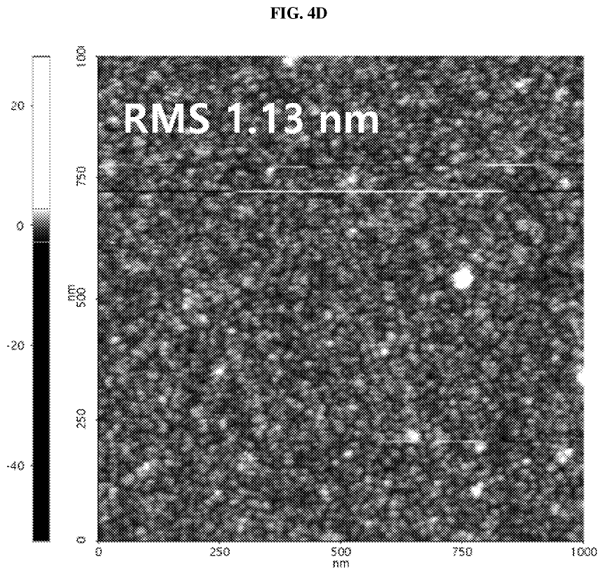

FIGS. 4A to 4D are atomic force microscope (AFM) images comparing surface roughness of an Au thin film according to Example 1 and Au thin films according to Comparative Examples 1, 2, and 3, respectively. The measured RMS surface roughness (in nm) was 0.70 for Example 1 (the present disclosure), 2.56 for Comparative Example 1 (spark discharge), 1.42 for Comparative Example 2 (vacuum thermal evaporation), and 1.13 for Comparative Example 3 (vacuum sputter), and it can be confirmed that the thin film manufactured by the method according to Example 1 has a low surface roughness value despite being very thin.

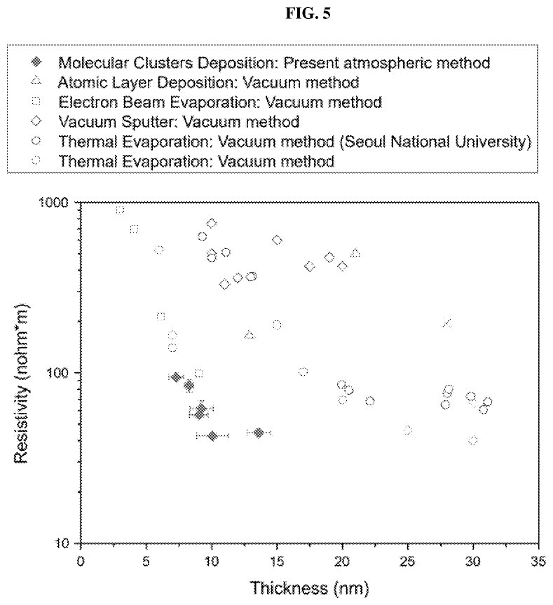

In addition, resistivities were measured using a four-point probe. According to the measurement results in FIG. 5, the 10 nm thick Au thin film according to Example 1 exhibited a resistivity of less than 50 nΩ·m. Notably, this value is comparable to, or lower than, the resistivity of the 30 nm thick Au thin film prepared by conventional vacuum thermal evaporation (Comparative Example 2), despite the significantly smaller film thickness. Since resistivity generally increases as film thickness decreases, these results demonstrate that the present method is capable of producing highly conductive thin films even at substantially reduced thicknesses compared with conventional vacuum deposition processes. In contrast, the Au thin film prepared by the conventional spark discharge method (Comparative Example 1) exhibited a resistivity approximately 30 times higher than that of Example 1.

From the above results, it can be seen that according to the present disclosure, thinner and more highly conductive thin films may be manufactured than existing vacuum thermal deposition processes without additional processes at ambient temperature and atmospheric pressure.

### Example 2

### Manufacturing of Tin Thin Film

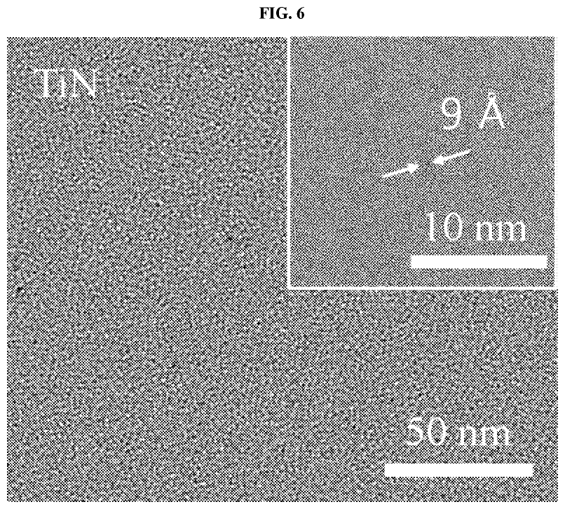

Positively charged TiN molecular cluster aerosols of several Å in size could be prepared by keeping the remaining conditions the same as in Example 1, except that a Ti wire electrode was used to produce the TiN molecular cluster aerosols by flowing N₂ as a carrier gas (see FIG. 6), and TiN molecular clusters generated at atmospheric pressure were accelerated and attached by an electric field to manufacture TiN thin films with thicknesses of about 5 nm, respectively.

FIG. 6 is a TEM image of TiN molecular cluster aerosols according to Example 2. Copper (Cu) was used as the third electrode 20 in the deposition chamber 200, and a silicon substrate with a silicon dioxide (SiO₂) thin film deposited to a thickness of 100 nm was used as the substrate 22. By applying a negative voltage of 5 kV to the substrate electrode, positively charged molecular cluster aerosols generated in the discharge chamber 100 was accelerated and attached by an electric field to manufacture TiN thin films with thicknesses of 5 nm, respectively.

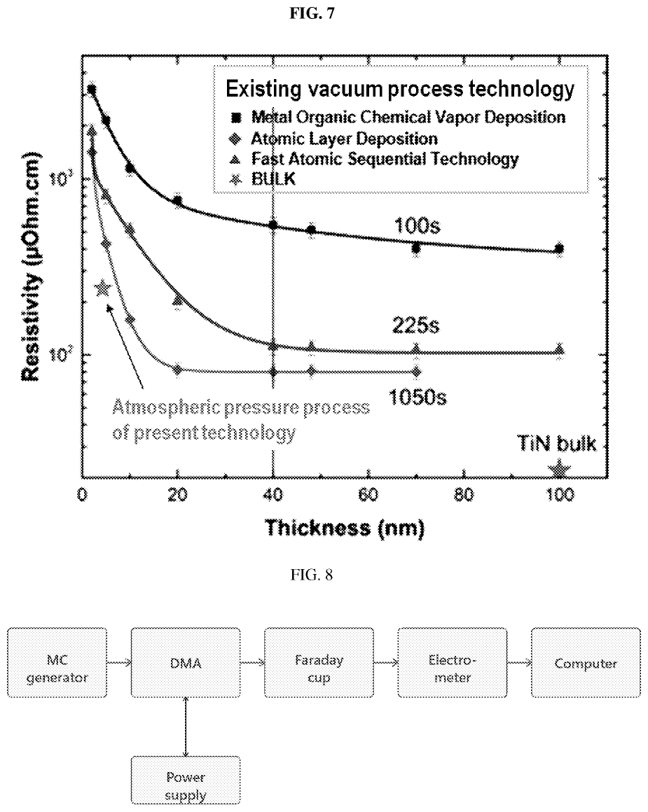

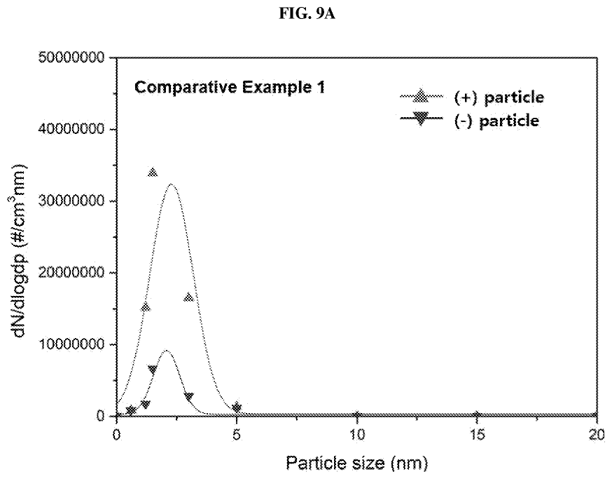

The resistivity of these TiN thin films was measured to be 228 μΩ·cm, respectively. FIG. 7 shows a comparison of the resistivity of the TiN thin films manufactured in this manner with the resistivity of thin films reported in previous studies. When compared at the same thickness, the resistivity was much lower than that of metal-organic chemical vapor deposition (MOCVD) or fast atomic sequential technology (FAST), as well as atomic layer deposition (ALD).

### Example 3

### Analysis of Particle Characteristics of Molecular Cluster Aerosols Unipolar Characteristics of Charged Particles

The molecular cluster aerosols generated by the method according to the present disclosure possess unipolar charge characteristics. Specifically, while bipolar charged particles, in which positive (+) and negative (−) charged particles occur simultaneously, are generated in the conventional spark discharge method, unipolar positive (+) charged molecular cluster aerosols are generated in the atmospheric pressure plasma discharge using an asymmetric electric field according to the present disclosure. This unipolar characteristic reduces inter-particle repulsion, enabling the formation of smaller particles and contributing to improved substrate adhesion efficiency by the electric field.

### Particle Size Distribution Measurement

The molecular cluster aerosols generated according to the present disclosure have a geometric diameter of about 1 nm, making them difficult to measure using a conventional particle size distribution measuring device, such as a scanning mobility particle sizer (SMPS), which typically measures particles larger than 2 nm. Accordingly, a measurement system combining a differential mobility analyzer (DMA), a Faraday cup, and an electrometer was configured to measure the size distribution of the particles generated by the present disclosure (see FIG. 8).

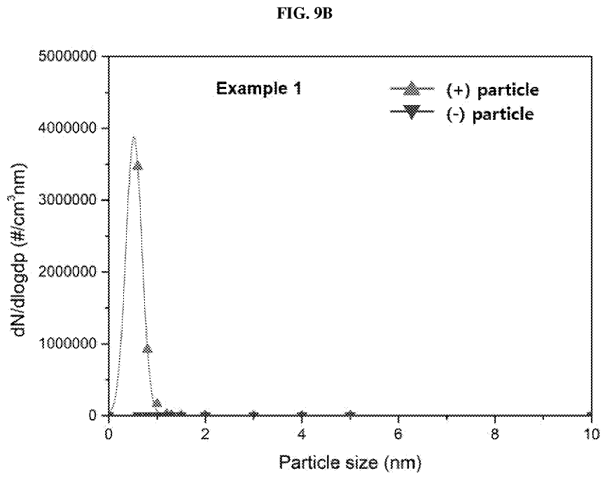

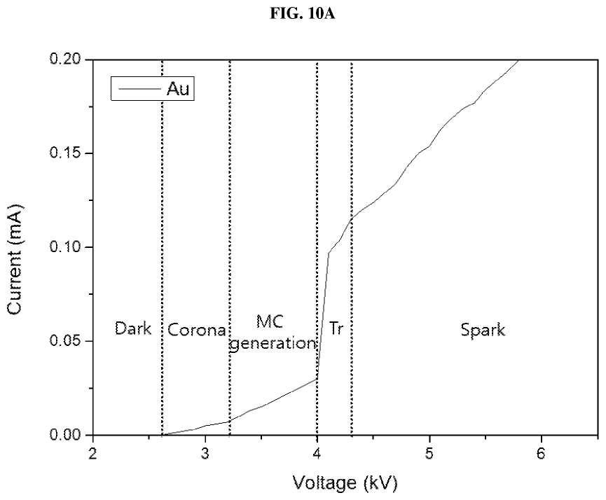

As a result of the measurement, both positive (+) and negative (−) charged particles were observed in the Au particles generated by spark discharge, exhibiting a size distribution in the range of approximately 2 to 5 nm (see FIG. 9A), whereas only positive (+) charged particles were observed in the Au particles generated by the method according to the present disclosure, exhibiting a very narrow and small size distribution of approximately 0.5 to 1 nm or less (see FIG. 9B). This experimentally supports the fact that the molecular cluster aerosols according to the present disclosure have a significantly smaller size compared to the nanoaerosol generated by spark discharge.

### Example 4

### Identification of the Molecular Cluster Generation Region Through I-V Characteristic Analysis

### Four Region I-V Characteristics

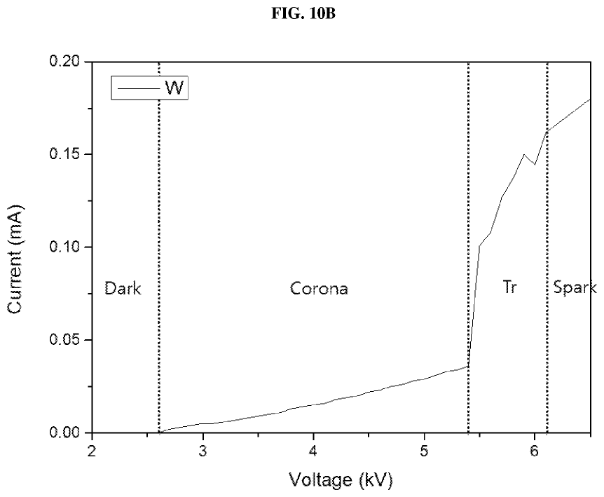

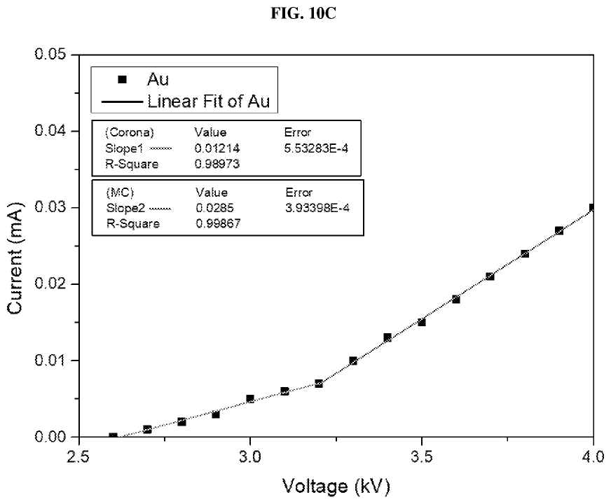

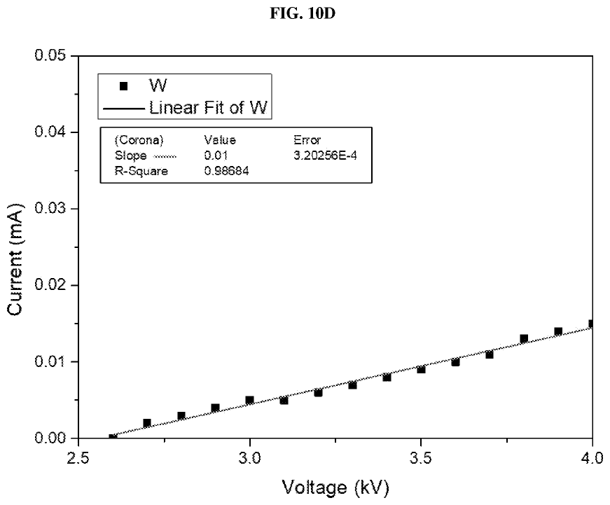

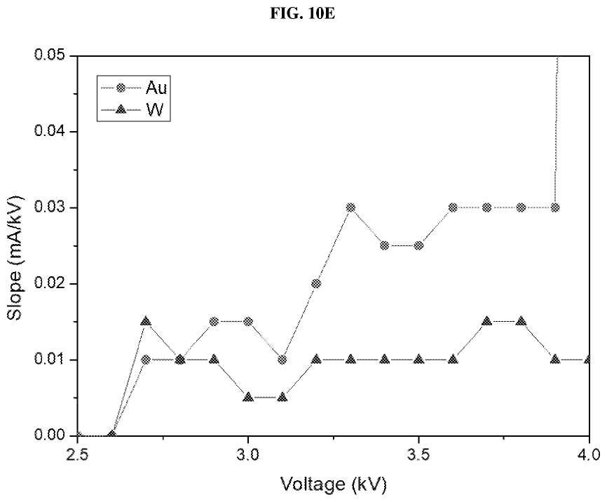

As shown in FIG. 10A, when the applied voltage was incrementally increased using Au electrode, four distinct regions were sequentially observed in the current-voltage (I-V) characteristics:
Region 1. Corona discharge region: A region in which corona discharge occurs near the electrode due to the strong electric field at low applied voltages. The current increases with a relatively moderate slope as a function of applied voltage.
Region 2. Molecular cluster (MC) generation region: A region in which the slope of the I-V curve differs distinctly from that of region 1. This is the region in which charged molecular cluster aerosols of a few angstroms in size are generated according to the present disclosure.
Region 3. Transition region: An intermediate region between the MC generation region and the onset of spark discharge.
Region 4. Spark discharge region: A region in which spark discharge occurs between the two electrodes, accompanied by a sharp increase in current.

FIG. 10B is I-V curve when tungsten electrode was used as the first electrode. The curve does not show distinct slope change in contrast to the case of Au. In this case, W molecular clusters were not generated due to high vaporization temperature of W.

### Difference in I-V Slope Between the Corona Discharge Region and the Molecular Cluster Generation Region

FIG. 10C presents an enlarged view of the difference in I-V slope between the corona discharge region (region 1) and the molecular cluster generation region (region 2). The enlarged I-V curve can be divided into two distinct regions having different average slopes. A first average slope of approximately 0.01 mA/kV is observed in the corona discharge region at power supply voltages below approximately 3.2 kV, whereas a second average slope of approximately 0.03 mA/kV is observed in the molecular cluster generation region at power supply voltages above approximately 3.2 kV. The change in slope between the two regions suggests that the discharge mechanism undergoes a qualitative transition, rather than representing a continuous extension of corona discharge. The generation of molecular cluster aerosols in the present disclosure occurs within region 2, which is attributed to atmospheric-pressure, low-temperature plasma discharge associated with the generation of metal molecular clusters that is mechanistically distinct from both corona discharge and spark discharge.

### Identification of a Novel Discharge Region Through Comparison With Tungsten (W) Electrode Corona Discharge

As a reference for pure corona discharge that generates only ions without producing molecular clusters, the I-V characteristics of a tungsten (W) electrode—known not to generate molecular clusters—were measured and compared with the I-V curves of Au electrode (FIG. 10B). In the plasma discharge I-V curves of Au electrode, four distinct regions are identified based on slope: the corona discharge region, the molecular cluster (MC) generation region, the transition region (Tr), and the spark discharge region. Notably, a change in I-V slope is observed between corona and molecular cluster generation regions. In contrast, for the W electrode, which generates only ions, no slope change is observed in the regions preceding the transition region (Tr) (FIG. 10D). The W I-V curve shows almost constant slope of approximately 0.01 mA/kV, which is similar to that of the Au corona discharge region. FIG. 10E presents the variation of the I-V curve slop shown in FIG. 10C and FIG. 10D. For the Au electrode, the slope remains within less than 50% variation at voltages below about 3.15 kV. However, between approximately 3.15 kV and 3.25 kV, the slope increases by more than 50% (up to 230%), indicating a distinct transition between the corona discharge region and the molecular cluster generation region. Accordingly, this voltage range may be used to define the boundary between the corona discharge region and the molecular cluster generation region. In contrast, for the W electrode, no slope increase greater than 50% is observed before the transition region, with the slope variation remaining less than 50%. From this comparison, the region 2 molecular cluster generation region exhibits a slope clearly distinct from the corona discharge I-V slope of the W electrode, experimentally confirming that this region is not a mere extension of corona discharge, but rather a novel discharge region unique to the present invention in which the electrode material vaporizes and undergoes adiabatic expansion to form molecular cluster aerosols of a few Å in size. In other words, the molecular cluster aerosol generation discharge of the present invention is an independent discharge phenomenon clearly distinct from both conventional corona discharge and spark discharge, as supported by I-V characteristic analysis.

As described above, the present disclosure enables the manufacturing of highly conductive thin films of conductive materials, such as metals, metal alloys, or metal oxides, with high quality using a simple apparatus without high vacuum that requires conventional sputter or thermal evaporate method. Therefore, it may be utilized in various fields such as environment, energy, food, cosmetics, semiconductors, and medicine where nanoparticle fabrication technology and highly conductive thin film deposition technology are required.

Although specific parts of the present disclosure have been described in detail above, it will be apparent to those skilled in the art that such specific descriptions are merely preferred embodiments and do not limit the scope of the present disclosure. Accordingly, the actual scope of the present disclosure is defined by the claims and equivalents thereof.

The present disclosure is the result of research conducted with the support of the following tasks.

### (1) Project No.: RS-2023-00282896

Unique Project Number: 1711200108
Ministry: Ministry of Science and ICT
Project Management (Specialized) Agency Name: National Research Foundation of Korea
Research Project Name: 2023 Nano and Materials Technology Development Project NanoConnect
Research Project Title: Development of High Conductivity and High Transmittance Flexible Transparent Electrodes Including 3D Nanoelectrodes and Development of Ultralightweight, High-Efficiency, High-Stability Flexible Perovskite Solar Cells Using the Same
Project Performing Organization Name: Multiscale Energy Systems Research Foundation
Research Period: 2023.08.01~2026.06.30

### (2) Project No.: Rs-2023-00279529

Announcement No.: No. 2023-0524
Project Name: Excellent Research—Mid-Career Research (Type 1-2)
Project Title: Pulse Engineering for Ensuring Long-term Stability of Large-Area Broadband Bandgap Perovskite Solar Cells
Total Project Period: 2023-09-01~2027-02-28
Contract Period: 2023-09-01~2027-02-28
Lead Research & Development Institution: Multiscale Energy Systems Research Foundation
Business Registration No.: 1198208369
Representative: Choi Man-soo
(Overall) Principal Investigator: Choi Man-soo

What is claimed is:

1. A method of depositing a conductive thin film, the method comprising:
generating charged molecular cluster aerosols of a conductive material by forming an asymmetric electric field under ambient temperature and atmospheric pressure conditions in a discharge chamber provided with a discharge electrode unit comprising a plurality of electrodes having different shapes, thereby causing a discharge to occur at one of the electrodes; and
introducing the molecular cluster aerosols into a deposition chamber fluidly connected to the discharge chamber and equipped with a substrate, and accelerating the molecular cluster aerosols with an electric field to attach the molecular cluster aerosols to the substrate.

2. The method of claim 1, wherein each charged molecular cluster aerosol is an aggregate of molecules each having a size of less than 1 nm and is a charged microparticle having an overall size of 2 nm or less.

3. The method of claim 1, wherein the plurality of electrodes comprises a first electrode connected to a power supply device and a second electrode which is a ground electrode, the first electrode and the second electrode are spaced apart by a predetermined distance, and the deposition chamber is provided with a third electrode in contact with the substrate.

4. The method of claim 3, wherein an electric field is accelerated by applying, to the third electrode, a voltage of opposite polarity to a voltage applied to the first electrode.

5. The method of claim 3, wherein a voltage of 1 to 10 kV is applied to the first electrode, the second electrode is grounded, a voltage of −1 to −10 kV is applied to the third electrode, a discharge voltage is 1 to 1,000 V.

6. The method of claim 3, wherein the first electrode has a wire shape having a predetermined diameter, and the second electrode has a plate shape having an opening part corresponding to the wire shape.

7. The method of claim 6, wherein the distance between the first electrode and the second electrode corresponds to the diameter of the first electrode.

8. The method of claim 1, wherein the charged molecular cluster aerosols are unipolarly charged.

9. The method of claim 1, wherein a particle size distribution of the charged molecular cluster aerosols is concentrated at 1 nm or less when measured using a measurement system comprising a differential mobility analyzer (DMA), a Faraday cup, and an electrometer.

10. The method of claim 1, wherein the discharge electrode unit comprises electrodes made of a conductive material selected from the group consisting of gold (Au), titanium (Ti), silver (Ag), palladium (Pd), copper (Cu), metal alloys thereof, and metal oxides including indium tin oxide (ITO).

11. The method of claim 1, wherein a carrier gas comprising at least one of nitrogen, argon, helium, hydrogen, oxygen, and their mixtures is injected into the discharge chamber at a flow rate of 0.1 to 100 l/min per electrode.

12. The method of claim 1, wherein the deposited conductive thin film has an RMS surface roughness of 0.7 nm or less as measured by atomic force microscopy (AFM).

13. The method of claim 1, wherein the deposited conductive thin film has a resistivity of less than 50 nΩ·m or less at a thickness of 10 nm.

14. The method of claim 1, wherein the conductive thin film has a thickness of 4 to 30 nm.

15. The method of claim 6, wherein the diameter of the first electrode and the opening part diameter of the second electrode are each independently 0.8 mm or more and 2 mm or less.

16. The method of claim 7, wherein the distance between the first electrode and the second electrode is 0.5 to 1.5 mm.

17. The method of claim 1, wherein the discharge electrode unit is provided in a plurality within the discharge chamber, and each discharge electrode unit independently injects a carrier gas.

18. The method of claim 1, wherein the discharge in the discharge chamber operates in a molecular cluster (MC) generation region that is sequentially identified in a current-voltage (I-V) characteristic curve as one of four distinct regions comprising a corona discharge region, the molecular cluster generation region, a transition region (Tr), and a spark discharge region, with increasing applied voltage.

19. The method of claim 18, wherein the slope of the I-V characteristic curve varies by less than 50% within the corona discharge region and increases by more than 50% at the beginning voltage of the molecular cluster generation region, thereby defining a boundary between the corona discharge region and the molecular cluster generation region.
